(19) United States
(12) Patent Application Publication
(10) Pub. No.: US 2026/0187319 A1
(43) Pub. Date: Jul. 2, 2026

(54) MACHINE LEARNING OPERATIONS PIPELINE FOR GAS-OIL RATIO ESTIMATION

(71) Applicant: Schlumberger Technology Corporation, Sugar Land, TX (US)

(72) Inventors: Liangyu Xu, Sugar Land, TX (US); Cheolkyun Jeong, Sugar Land, TX (US)

(21) Appl. No.: 19/431,574

(22) Filed: Dec. 23, 2025

Related U.S. Application Data
(60) Provisional application No. 63/739,731, filed on Dec. 30, 2024.

(51) Int. Cl. G06F 30/27

(52) U.S. Cl. CPC G06F 30/27

(57) ABSTRACT

A system and method for estimating gas-oil ratio (GOR) in an Optical cartridge (OC) firmware is provided. Specifically, optical densities may be mapped to carbon composition and the carbon composition may be mapped to the GOR. Machine learning may enhance the GOR estimation, specifically by providing enhancements to the mapping of the optical densities to carbon composition and/or mapping of the carbon composition to the GOR. A machine learning operations (MLOps) pipeline may be provided to facilitate the machine learning.

### CROSS-REFERENCE TO RELATED APPLICATION

This application claims priority to and benefit of U.S. Provisional Application No. 63/739,731, entitled “Machine-Learning-Operations-Pipeline for Gas-Oil Ratio Estimation,” filed on Dec. 30, 2024, which is hereby incorporated by reference in its entirety.

### BACKGROUND

The petroleum industry relies on accurate estimation models for Gas-Oil Ratio (GOR) to optimize production and reservoir management. Logging While Drilling (LWD) tools are essential in the oil and gas industry for obtaining real-time downhole measurements during the drilling process. While some LWD tools can provide valuable information about reservoir properties and fluid composition, estimating the Gas-Oil Ratio (GOR) directly can be challenging. SpectraSphere™ (also known as JPG) is an LWD tool that provides fluid mapping while drilling services. Its Pump Out Module (POM) contains a displacement pump and two downhole fluid analyzers ahead and after the pump. Each downhole fluid analyzer has an optical spectrometer, and the measured Optical Densities (ODs) are used to estimate fluid type, carbon composition, and Gas Oil Ratio (GOR) in real-time. The downhole fluid analyzer may also be referred to as an optical cartridge (OC) or JPG Optical cartridge (JPOC).

The Gas-Oil Ratio (GOR) estimation model employed in JPOC may benefit from enhancement, as certain field cases exhibit discrepancies in estimated values compared to GOR values measured in PVT (Pressure-Volume-Temperature) laboratory settings. Moreover, traditional methods face challenges in adapting to incorporating new data frequently.

### BRIEF DESCRIPTION OF THE DRAWINGS

The present disclosure is best understood from the following detailed description when read with the accompanying Figures. It is emphasized that, in accordance with the standard practice in the industry, various features are not drawn to scale. In fact, the dimensions of the various features may be arbitrarily increased or reduced for clarity of discussion.

FIG. 1 is a schematic drilling rig including a drill string and a bottom hole assembly deployed in the string disposed within a wellbore, according to one or more aspects of the disclosure.

FIG. 2 is an illustration of a fluid sampling and evaluation measurement tool depicted in a wellbore (e.g., as shown in FIG. 1) , according to one or more aspects of the disclosure.

FIG. 3 is an illustration of a portion of downhole measurement tool of FIG. 2, according to one or more aspects of the disclosure.

FIG. 4 is a flowchart, illustrating functionality of a machine-learning operations (MLOps) pipeline, according to one or more aspects of the disclosure.

FIG. 5 is a basic analytics engine workflow for stacking data from three sources (DBR, field, FISO VnV (e.g., optical verification and validation)) and adding normalization/augmentation for pre-processing, according to one or more aspects of the disclosure.

FIG. 6 is an illustration of a series of model evaluations and comparisons to select a GOR estimation model, according to one or more aspects of the disclosure.

FIG. 7 is an illustration providing an example scenario that automates the model building, dataset building, notebook updating, and dashboard refreshing based upon received updated datasets, according to one or more examples of the disclosure.

### DETAILED DESCRIPTION

Illustrative examples of the subject matter claimed below will now be disclosed. In the interest of clarity, not all features of an actual implementation are described in this specification. It will be appreciated that in the development of any such actual implementation, numerous implementation-specific decisions may be made to achieve the developers'specific goals, such as compliance with system-related and business-related constraints, which will vary from one implementation to another. Moreover, it will be appreciated that such a development effort, even if complex and time-consuming, would be a routine undertaking for those of ordinary skill in the art having the benefit of this disclosure.

Further, as used herein, the article “a” is intended to have its ordinary meaning in the patent arts, namely “one or more.” Herein, the term “about” when applied to a value generally means within the tolerance range of the equipment used to produce the value, or in some examples, means plus or minus 10%, or plus or minus 5%, or plus or minus 1%, unless otherwise expressly specified. Further, herein the term “substantially” as used herein means a majority, or almost all, or all, or an amount with a range of about 51% to about 100%, for example. Moreover, examples herein are intended to be illustrative only and are presented for discussion purposes and not by way of limitation.

GOR (gas-oil ratio) estimation is a challenging task for the JPG Optical cartridge (JPOC). JPOC is the downhole fluid analyzer for SpectraSphere™ (also known as JPG) LWD tool. The measured Optical Densities (ODs) from optical spectrometers (e.g., in JPOC) may be used to estimate GOR in real-time. However, in some field jobs, differences are observed between the GOR estimations from the two JPOCs resident in a single JPG bottom-hole assembly (BHA) and between these estimations and the PVT laboratory-measured values. Accordingly, a JPOC Reconciliation process may attempt to address the observed differences.

The process of estimating GOR in fluid analyzer (e.g., JPOC) firmware implementation involves two main steps. Firstly, ODs may be mapped to carbon composition (e.g., using a B matrix generated through the Partial Least Squares (PLS) algorithm on a dataset (e.g., that contains 71 oils, 32 gas condensates, and 33 gases)). Subsequently, the carbon composition may be mapped to GOR (e.g., using a legacy Artificial Neural Network (ANN) model).

Improved estimation of Gas-Oil Ratio (GOR) attributed to a reservoir/formation may be provided via machine learning. Specifically, a summary-expanded database for Machine-Learning (ML) Operations (MLOps) may be generated and used for accurate GOR modelling and/or estimation. ML-based alternative estimation techniques for one or both steps (OD to carbon composition mapping and carbon composition to GOR) may be implemented. The ML-based alternative methods may include any number of ML models, such as: new PLS, KernelPLS_rbf, KernelPLS_Nystroem, KernelPLS_Polynominal, Random Forest, k Nearest Neighbor, and Gradient Boost.

Enhanced datasets are constant becoming available to provide additional data that may be useful for GOR estimation. For example, constant efforts are underway in collaboration with SRL (Schlumberger Reservoir Laboratories) and SDR (Schlumberger Doll Research) to collect additional data to enhance the datasets used for carbon composition and/or GOR mapping. In response to the new data, the GOR estimation models require retraining. Instead of manually training the models periodically, the MLOps pipeline may be provided to automate this process, resulting in fast adjustment of fluid analysis, resulting in improved GOR estimation.

To implement the ML-based alternative methods, the MLOps pipeline is designed specifically for identifying and/or updating the optimal GOR estimation model (e.g., for the fluid analyzer (e.g., JPOC)) using an expanded database (e.g., including the enhanced datasets). The MLOps pipeline seamlessly incorporates the new datasets into prospective optimal Gas-Oil Ratio estimation models by employing automatic model retraining and re-evaluation processes. It then dynamically selects and/or records the GOR estimation model that exhibits the best performance.

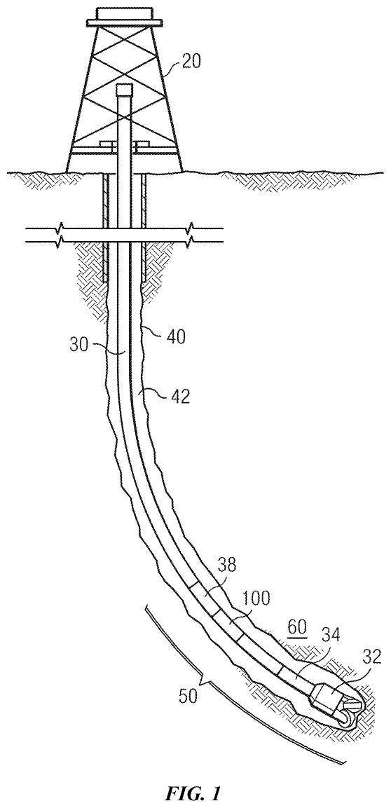

FIG. 1 depicts a schematic drilling rig 20 including a drill string 30 and a bottom hole assembly 50 deployed in the string disposed within a wellbore 40. The drilling rig 20 may be deployed in either onshore or offshore applications (an onshore application is depicted). Moreover, the wellbore may be inclined at substantially any angle and may include vertical, horizontal, and building sections (only vertical and building sections are depicted). The disclosed embodiments are not limited to any particular wellbore configuration. In the depicted example, the wellbore 40 may be formed in subsurface formations by rotary drilling in a manner that is well-known to those or ordinary skill in the art (e.g., via well-known directional drilling techniques).

The drill string 30 may be rotated, for example, at the surface to drill the well (e.g., via a rotary table or via a hydraulically powered motor deployed in or above the bottom hole assembly (BHA) 50). A pump may deliver drilling fluid through the interior of the drill string 30 to the drill bit 32 where it exits the string via ports therein. The fluid may then circulate upwardly through the annular region 42 between the outside of the drill string 30 and the wall of the wellbore 40. In this manner, the drilling fluid lubricates the drill bit 32 and carries formation cuttings up to the surface.

In the illustrated example embodiment, the BHA 50 may include any number of downhole tools, for example, including a steering tool 34 and a measurement while drilling (MWD) tool 38. As depicted the BHA further includes an LWD fluid sampling and evaluation measurement tool 100. As described in more detail below, measurement tool 100 may be configured to obtain a formation fluid sample and to analyze the sample to estimate a composition of the formation fluid. The BHA may optionally include other LWD tools, one or more stabilizers, as well as other tools such as a reamer. The disclosed embodiments are not limited to any particular BHA configuration.

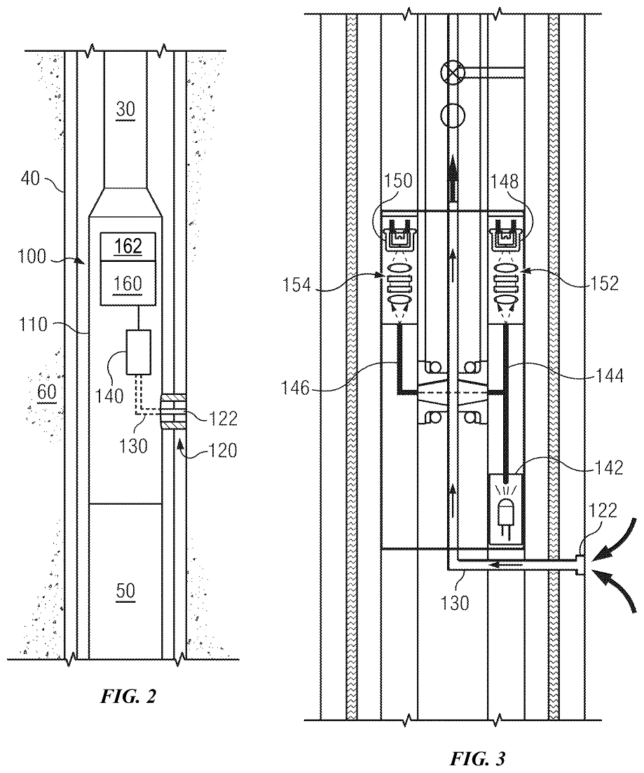

Turning now to FIG. 2, one example embodiment of a fluid sampling and evaluation measurement tool 100 (e.g., a fluid analyzer and/or JPOC) is depicted in a wellbore (e.g., as shown in FIG. 1). Measurement tool 100 may include a downhole tool body 110 such as an LWD tool body configured for deployment in (and coupling with) a BHA in a drill string. For example, the tool body may include threaded ends (not shown) for coupling with the drill string and may be configured to withstand the harsh drilling environment including severe shocks and vibrations. The measurement tool 100 may further include a probe 120 configured to engage a wellbore wall and to pump or draw wellbore fluid into the tool via an input port 122. The input port 122 is in fluid communication with an internal flowline 130 and at least one optical measurement assembly 140 that is configured to make optical absorption measurements of the wellbore fluid. A controller 160 may be configured to operate the measurement tool 100 as well as evaluate and interpret optical measurements made using the optical measurement assembly 140 as described in more detail below. While the example embodiment depicted on FIG. 2 does not depict a sampling pump, it will be appreciated that a sampling pump may be deployed along flowline 130 or above assembly 140 such that it draws the fluid through the assembly 140. The disclosed embodiments are, of course, not limited in this regard.

The controller 160 and connected components may be further configured to execute all and/or a portion of the disclosed techniques (e.g., process 170) described in more detail below with respect to FIG. 3). It will, of course, be appreciated that the controller may include computer hardware and software configured to cause the measurement tool to make the optical measurements (for example to cause the optical measurement assembly to make optical measurements during a non-drilling interval) as well as to automatically execute one or more of the disclosed methods. The hardware may include one or more processors (e.g., microprocessors) which may be connected to one or more data storage devices (e.g., hard drives or solid-state memory) and user interfaces. It will be further understood that the disclosed embodiments may include processor executable instructions stored in the data storage device. The disclosed embodiments are, of course, not limited to the use of or the configuration of any particular computer hardware and/or software.

As illustrated, the controller 160 may include and/or be communicatively coupled to an MLOps pipeline 162, which may be disposed wholly and/or partially within evaluation measurement tool 100 or may be wholly external but in communication with evaluation measurement tool 100. As mentioned above, the MLOps pipeline 162 is tasked with augmenting and/or using a summary expanded database in MLOps to identify and use prospective optimal GOR estimation models based upon new data samples (e.g., Optical Density measurements obtained via the evaluation measurement tool 100) are retrieved. In this manner, one or more prospective optimal GOR estimation models may be identified and used (e.g., periodically), to provide dynamically refreshed GOR estimation, potentially resulting in significant accuracy improvements in GOR estimation, which may improve production and reservoir management (e.g., through subsequent drilling parameter modifications based upon the improved GOR estimation.

Turning now to FIG. 3, a portion of downhole measurement tool 100 is schematically depicted. As described above with respect to FIG. 2, measurement tool 100 includes a probe having an input port 122 in fluid communication with an internal flowline 130. In example embodiments, the optical measurement assembly 140 may include a light source 142, a reference signal path 144 and a sample or measurement signal path 146. The light source 142 may include, for example, a halogen lamp, a light-emitting diode, a laser, or any other suitable optical source. The reference signal path 144 may include an optical fiber that couples the light source 142 with a first detector 148 (e.g., a first spectrometer) and the sample or measurement signal path 146 may include an optical fiber that couples the light source 142 with a second detector 150 (e.g., a second spectrometer). Each of the signal paths 144, 146 may further include a corresponding lens and bandpass filter arrangement 152, 154 configured to focus and filter light emanating from the light source such that the light received by the detectors/spectrometers 148, 150 is within a particular frequency band. In example embodiments, optical absorption measurements may be made at a predetermined number of discrete optical wavelengths in the visible and near infrared (e.g., 20 discrete wavelengths in a band ranging from about 400 nm to about 2100 nm).

With continued reference to FIG. 3, the detectors/spectrometers 148, 150 are in electronic communication with the controller 160. In operation, the light source 142 emits light that traverses both the reference signal path 144 and the measurement signal path 146. As depicted, the light traversing the measurement signal path 146 passes through a transparent portion of the flowline 130 and the corresponding formation fluid within the flowline 130. The controller may be configured to generate an optical density spectrum from the detector measurements made at each of the detectors/spectrometers 148, 150. Moreover, the controller may be configured to cause the measurement tool 100 to make the optical measurements at substantially any suitable time interval, for example, at a frequency in a range from about 1 to about 10 Hz. The disclosed embodiments are of course not limited in this regard.

The optical densities generated via the evaluation measurement tool 100 (e.g., at periodic frequencies) may be used to augment a summary expanded database containing JPOC-measured Optical Densities (ODs) and Pressure-Volume-Temperature (PVT) laboratory-measured GOR values). As mentioned above, the MLOps pipeline 162 may update the optimal GOR estimation model (e.g., for JPOC) using this expanded database. The MLOps pipeline 162 may seamlessly incorporate new datasets into prospective optimal Gas-Oil Ratio estimation models by employing automatic model retraining and re-evaluation processes as new datasets become available. The MLOps pipeline 162 may then identify and/or record the GOR estimation model that exhibits the best performance (e.g., by comparing model estimations with laboratory measured GORs).

The MLOps pipeline provides automated and dynamic management of machine learning models, ensuring their continuous relevance and accuracy in response to evolving input data. The automation of model retraining ensures that machine learning models remain current and effective, dynamically adapting to changes in the input data landscape without the need for manual intervention.

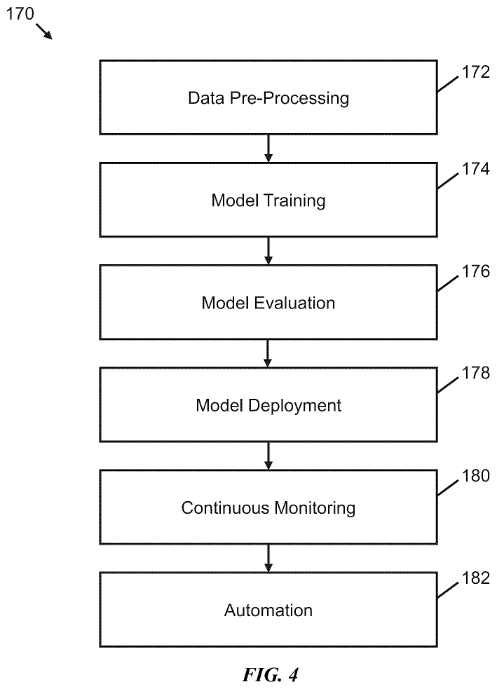

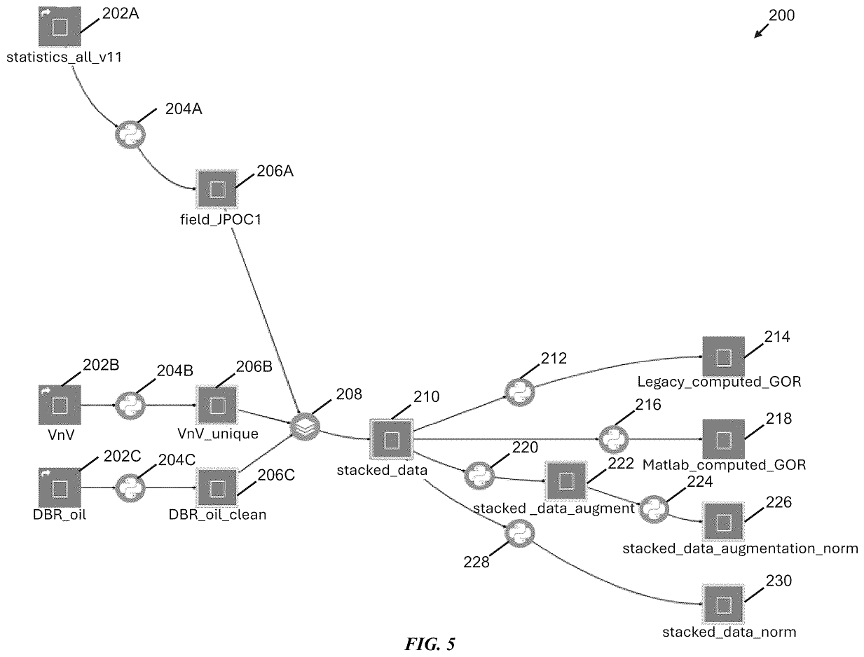

FIG. 4 is a flowchart of a process 170 illustrating functionality of the MLOps pipeline 162. In some cases, the MLOps pipeline 162 functionality disclosed herein may be established within a data analytics software platform, a collaborative environment designed for advanced data science and machine learning activities. Certain data analytics software platform visualizations are provided herein for discussion purposes, where data analytics software platform flows may be used to control: data pre-processing, model training, model evaluation, and model deployment; data analytics software platform Dashboards and Scenarios may control continuous monitoring; and data analytics software platform Scenarios may be used to control automation. However, the disclosed embodiments are of course not limited in this regard and other suitable software platforms and equivalent software platform features may be used to implement the functionality of the MLOps pipeline 162 described herein.

As illustrated, the MLOps pipeline 162 may include a data pre-processing step 172. FIG. 5 is a data analytics software platform workflow illustration 200, illustrating data pre-processing step 172 implemented in the data analytics software platform. As illustrated, the current MLOps pipeline 162 takes in data from three data sources: 202A, 202B, and 202C. Data source 202A may include field captured statistics (e.g., retrieved during drilling operations within the reservoir/formation. Data source 202B may include validation and verification data source 202B (e.g., FISO VnV data source) and data source 202C may include Dynamic Reservoir Behavior (DBR) analysis results (e.g., identified via detailed fluid analysis (e.g., PVT) and phase behavior for oil and gas reservoirs, using advanced equipment (e.g., viscometers and digital tools) to understand how petroleum behaves under extreme conditions, enhancing recovery and production.

Corresponding scripts (e.g., python scripts 204A, 204B, 204C) may be used to clean up the data received from data sources 202A-202C. For example, data may be transformed to provide data in particular expected format different than that in which it is received, filtered to provide unique values only, etc.

Accordingly, the scripts 204A-204C may output corresponding cleaned up data 206A, 206B, and 206C, respectively. A stacking operation 208 may be used to stack (e.g., join) the cleaned-up data 206A-C for subsequent use and/or processing.

The stacked data 210 resulting from the stacking operation 208 may be used by script 212 to compute a legacy GOR 214. The stacked data 210 resulting from the stacking operation 208 may be used by script 216 to compute a Matlab computed GOR 218. The stacked data 210 resulting from the stacking operation 208 may be used by script 220 to augment the stacked data. The augmented stacked data 222 may be used by script 224 to generate normalized augmented stacked data 226. The stacked data 210 resulting from the stacking operation 208 may also be used by script 228 to generated normalized stacked data 230.

The legacy GOR 214, the Matlab computed GOR 218, the normalized augmented stacked data 222, and/or the normalized stacked data 230 may be the pre-processing step 172 outputs that are used for subsequent functionality of the MLOps pipeline. For example, returning to FIG. 4, the MLOps pipeline 162 may include a model training step 174 that uses all or some of these outputs.

In model training step 174, one or more custom regression models for GOR calculation with respect to the reservoir/formation may be created. Data training using the custom regression models may be performed. For example, each of the available models may be trained.

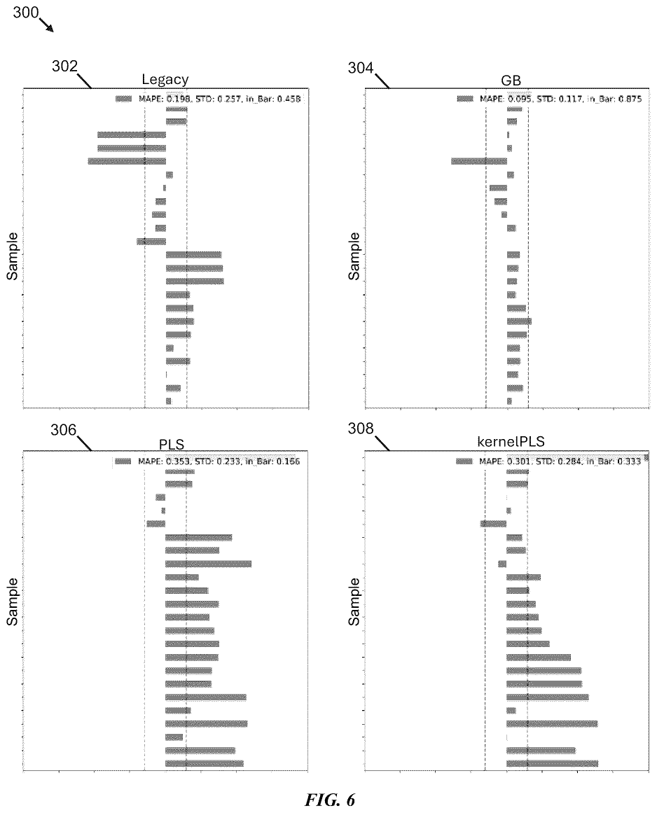

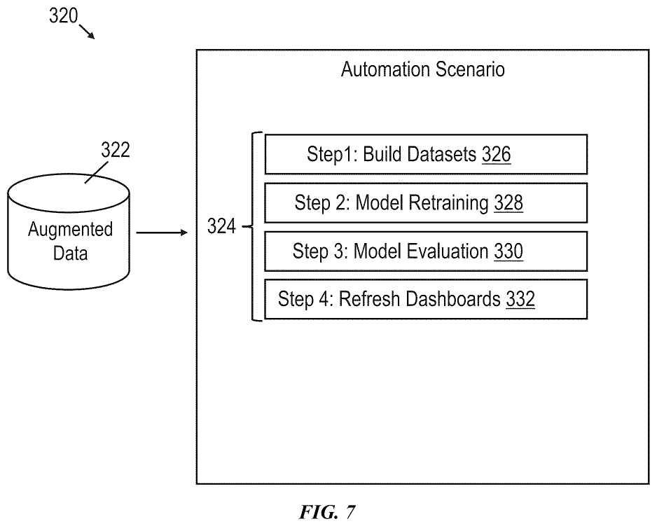

Returning to FIG. 4, the MLOps pipeline 162 may include a model evaluation step 176. In the model evaluation step 176, the trained models may be evaluated to identify a prospective optimal GOR estimation model that may be most accurate from the set of trained models. For example, FIG. 6 illustrates a subset of trained model results 300, where the model results may be compared with one another to identify a most accurate trained model for use in subsequent GOR estimation. In the illustrated example, legacy model results 302, gradient boost (GB) model results 304, Partial Least Squares (PLS) model results and kernel PLS model results are compared to identify a desirable model to use as the optimal GOR estimation model. Any number of models may be analyzed and/or compared to identify the optimal GOR estimation model. For example, analyzed models may include: PLS, KernelPLS_rbf (PLS regression with radial basis function (RBF) neural networks), KernelPLS_Nystroem (PLS combined with Nystrom method (e.g., a sampling strategy to efficiently approximate complex matrix functions), KernelPLS_Polynomial (using kernel methods for similarity/weighting and polynomial regression), Random Forest, k Nearest Neighbor, and Gradient Boost, to name a few.

Returning to FIG. 4, the MLOps pipeline 162 may include a model deployment step 178. In the model deployment step 178, the system is instructed to dynamically select and implement the identified optimal GOR estimation model for subsequent GOR estimation.

The MLOps pipeline 162 may include a continuous monitoring step 180. In the continuous monitoring step 180, captured metrics and/or identified estimates are dynamically shared via one or more dashboards (e.g., a data analytics software platform dashboard tasked with sharing data elements). Further, scenarios (e.g., a set of actions to complete with conditions to run the set of actions) may influence and/or control the continuous monitoring. Through the continuous monitoring, dynamic changes (e.g., altering the optimal GOR estimation model) may be performed as the models'accuracy changes.

The MLOps pipeline 162 may include an automation step 182. In the automation step 182, automated model retraining, model evaluation, result and dashboard generation may be provided when input data is updated. This automation may ensure that the machine learning models stay current and relevant, adapting to changes in the input data without manual human intervention. For example, FIG. 7 illustrates a data analytics software platform Automation Scenario GUI 320 used to automate building of a data set and/or training a model when augmented data 322 is received. Specifically, in the provided example, upon reception of laboratory data to augment datasets for training the models, the specified items 324 may be automatically triggered, resulting in updated training for the models, updated dashboards, etc. For example, as illustrated, in step 326, augmented datasets (e.g., incorporating the received augmented data 322) may be performed. Further, models may be retrained in step 328, the models may be evaluated in step 330, and the dashboards may be refreshed (e.g., with updated GOR estimates) in step 332.

Examples in the present disclosure may also be directed to a non-transitory computer-readable medium storing computer-executable instructions and executable by one or more processors of the computer via which the computer-readable medium is accessed. A computer-readable media may be any available media that may be accessed by a computer. By way of example, such computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Note also that the software implemented aspects of the subject matter claimed below are usually encoded on some form of program storage medium or implemented over some type of transmission medium. The program storage medium is a non-transitory medium and may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The claimed subject matter is not limited by these aspects of any given implementation.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific examples are presented for purposes of illustration and description. They are not intended to be exhaustive of or to limit this disclosure to the precise forms described. Obviously, many modifications and variations are possible in view of the above teachings. The examples are shown and described in order to best explain the principles of this disclosure and practical applications, to thereby enable others skilled in the art to best utilize this disclosure and various examples with various modifications as are suited to the particular use contemplated. It is intended that the scope of this disclosure be defined by the claims and their equivalents below.

What is claimed is:

1. A method for estimating gas-oil ratio (GOR) in an optical cartridge (OC) firmware comprising:
identifying a set of optical densities of one or more fluid samples of a formation during logging while drilling (LWD) operations on the formation;
mapping the optical densities to carbon composition;
mapping the carbon composition to the GOR;
validating the GOR against one or more estimation models;
selecting a GOR estimation model based upon validating the GOR; and
controlling subsequent estimation of GOR in the OC using the selected GOR estimation model.

2. The method of claim 1, wherein the method is enhanced using machine learning.

3. The method of claim 2, wherein the mapping the carbon composition to the GOR is performed using a legacy Artificial Neural Network (ANN).

4. The method of claim 1, wherein the method comprises data pre-processing, comprising:
receiving data from a plurality of different data sources;
cleaning the data from the plurality of different data sources (“cleaned data”);
stacking the cleaned data (“stacked data”);
augmenting the stacked data (“augmented data”); and
normalizing the augmented data.

5. The method of claim 4, comprising:
performing model training with different custom-created regression models based upon the data pre-processing, resulting in trained models.

6. The method of claim 5, comprising:
performing model evaluation on the trained models to identify a most accurate model as a desired GOR estimation model; and
deploying the desired GOR estimation model for subsequent GOR estimation.

7. The method of claim 6, comprising:
identifying target conditions for automation; and
in response to the target conditions being identified, triggering automation comprising:
automatic model retraining, model evaluation, result, and dashboard generation.

8. The method of claim 7, wherein the target conditions comprise receiving additional input data from one of the plurality of different data sources.

9. A system for estimating gas-oil ratio (GOR) in an Optical cartridge (OC) firmware, comprising:
a processor;
memory accessible to the processor;
processor-executable instructions stored in the memory and executable by the processor to instruct the system to:
map optical densities to carbon composition; and
map the carbon composition to the GOR;
wherein the mapping of the optical densities to carbon composition, the mapping of the carbon composition to the GOR, or both is enhanced using machine learning.

10. The system of claim 9, wherein the mapping the carbon composition to gas-oil ratio is performed using a legacy Artificial Neural Network (ANN).

11. The system of claim 9, comprising:
a machine-learning operations (MLOps) pipeline comprising hardware configured to:
perform data pre-processing;
train one or more machine-learning models;
evaluate the trained one or more machine-learning models to identify a most accurate model for GOR estimation; and
select and deploy the most accurate model for subsequent GOR estimation.

12. The system of claim 11, wherein the MLOps pipeline is configured to perform the data pre-processing by:
receiving the data from a plurality of different data sources;
cleaning the data from the plurality of different data sources (“cleaned data”);
stacking the cleaned data (“stacked data”);
augmenting the stacked data (“augmented data”); and
normalizing the augmented data.

13. The system of claim 12, wherein the MLOps pipeline is configured to perform:
continuous monitoring; and
automation.

14. The system of claim 13, wherein performing the automation comprises:
identifying target conditions for the automation; and
in response to the target conditions being identified, trigger the automation comprising:
automatic model retraining, updated model evaluation, updated result generation, and updated dashboard generation.

15. The system of claim 14, wherein the target conditions comprise receiving additional input data from one of the plurality of data sources.

16. The system of claim 12 comprising:
an Optical cartridge (OC) acting as one of the plurality of data sources during drilling.

17. A non-transitory, computer-readable medium, comprising computer-readable instructions that, when executed by one or more processors of one or more computers, cause the one or more computers to:
receive, from a downhole fluid analyzer optical cartridge (OC), fluid sample data;
map optical densities of the fluid sample data to carbon composition; and
map the carbon composition to a gas-oil ratio (GOR);
wherein the mapping of the optical densities to carbon composition, the mapping of the carbon composition to the GOR, or both is performed using machine learning.

18. The non-transitory, computer-readable medium of claim 17, comprising computer-readable instructions that, when executed by one or more processors of the one or more computers, cause the one or more computers to:
perform the machine learning, by:
receiving a reservoir dataset;
performing pre-processing on the reservoir dataset;
train one or more machine-learning models using the pre-processed reservoir dataset;
evaluate the trained one or more machine-learning models to identify a most accurate model for GOR estimation; and
select and deploy the most accurate model for subsequent GOR estimation of the fluid sample data.

19. The non-transitory, computer-readable medium of claim 18, wherein the pre-processing comprises:
cleaning the reservoir dataset (“cleaned data”);
stacking the cleaned data (“stacked data”);
augmenting the stacked data (“augmented data”); and
normalizing the augmented data.

20. The non-transitory, computer-readable medium of claim 18, comprising computer-readable instructions that, when executed by one or more processors of the one or more computers, cause the one or more computers to:
perform continuous monitoring; and
identify target conditions for automation; and
in response to the target conditions being identified, trigger the automation, wherein the automation comprises: automatic model retraining, updated model evaluation, updated result generation, and updated dashboard generation.
